(19) United States
(12) Patent Application Publication
(10) Pub. No.: US 2013/0149795 A1
(43) Pub. Date: Jun. 13, 2013

(54) ETCHING METHOD AND METHOD OF MANUFACTURING SEMICONDUCTOR DEVICE

(71) Applicant: Kabushiki Kaisha Toshiba, Tokyo (JP)

(72) Inventor: Kazuhiro Tomioka, Kanagawa-ken (JP)

(73) Assignee: Kabushiki Kaisha Toshiba, Tokyo (JP)

(21) Appl. No.: 13/713,388

(22) Filed: Dec. 13, 2012

(30) Foreign Application Priority Data
Dec. 13, 2011 (JP) 2011-272844

(51) Int. Cl. H01L 21/308

(52) U.S. Cl. CPC H01L 21/3081
USPC 438/3; 438/703

(57) ABSTRACT

In an etching method of an embodiment, a film to be etched, which includes a first metallic element, is formed on a semiconductor substrate. A carbide layer, which includes a second metallic element, is formed on the film to be etched. The carbide layer is etched. The film to be etched is etched by using the carbide layer as a mask.

### CROSS-REFERENCE TO RELATED APPLICATION(S)

This application is based upon and claims the benefit of priority from Japanese Patent Application No. 2011-272844, filed on Dec. 13, 2011; the entire contents of which are incorporated herein by reference.

### FIELD

Embodiments of the present invention relate to an etching method and a method of manufacturing a semiconductor device.

### BACKGROUND

Various semiconductor storage memories, such as DRAM (Dynamic Random Access Memory), FeRAM (Ferroelectric Random Access Memory) and MRAM (Magnetoresistive Random Access Memory), have been developed in these years. Films formed from noble metal elements like Pt, Ir and Ru are used as electrodes in these semiconductor storage memories in some cases.

In a conventional practice, films to be etched, which include noble metal elements or the like, are etched by RIE (Reactive Ion Etching), for example, with the wafer heated at high temperature, because the melting points of the films to be etched are so high that the reaction products by the RIE etching has a low steam pressure. This method, however, sometimes makes the masks tapered while etching the films to be etched. For this reason, it is difficult to perpendicularly etch the films to be etched.

### BRIEF DESCRIPTION OF THE DRAWINGS

FIGS. 1A to 1F are cross-sectional views showing an etching process of a first embodiment.

FIGS. 2A to 2F are cross-sectional views showing a method of manufacturing semiconductor device of a second embodiment.

### DETAILED DESCRIPTION

Descriptions will be provided hereinbelow for embodiments of the present invention by referring to the drawings.

### First Embodiment

Descriptions will be provided hereinafter for an etching method of a first embodiment.

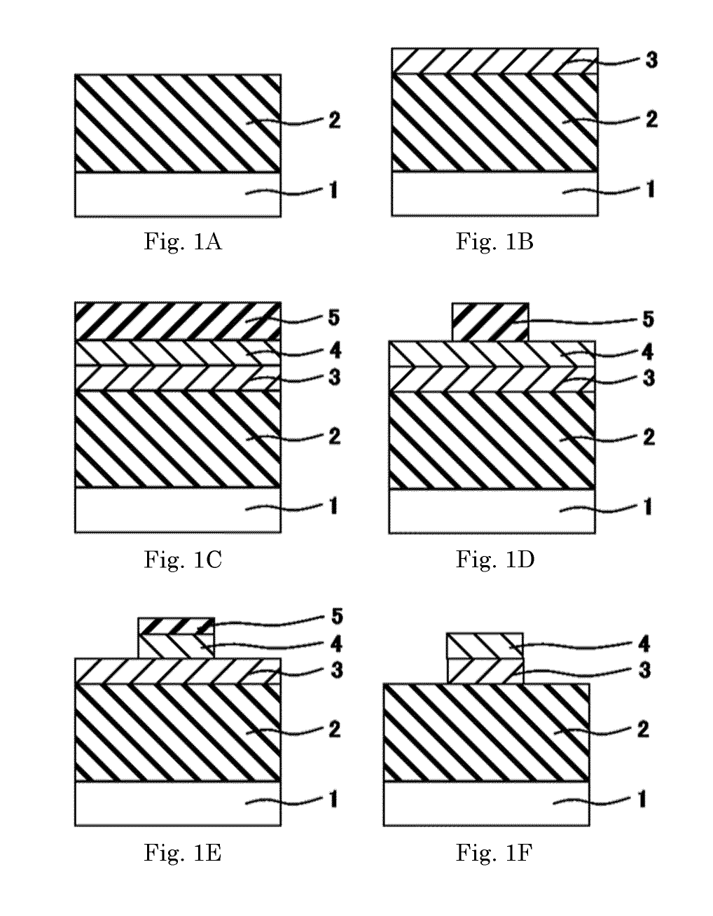

FIGS. 1A to 1F are cross-sectional views showing the etching method of the first embodiment.

As shown in FIGS. 1A to 1F, an interlayer dielectric 2 is formed on a semiconductor substrate 1. A silicon oxide film, for example, is used as the interlayer dielectric 2.

Subsequently, a film 3 to be etched is formed on the interlayer dielectric 2. The film 3 to be etched includes, for example, Pt, Au, Ag, Ir, Pd, Rh, Ru or Os as a second metallic element. The film 3 to be etched may include an element other than the noble metal elements. The film 3 to be etched may include, for example, an element of any one selected from Fe, Co, Ni, Cu, Zn, Pd, Ag, Ir, Pt, Zr, Hf, La and Sr.

Thereafter, a carbide layer 4 is formed on the film 3 to be etched. The carbide layer 4 includes: an element of carbon and an element of Ti, Ta, W, Mo, Nb or Hf as a first metallic element. A Tic film or a TaC film, for example, is used as the carbide layer 4. The TiC film or the TaC film is formed, for example by: sputtering with TiC or TaC used as a target; reactive sputtering in which Co is introduced with Ta used as a target; CVD (Chemical Vapor Deposition); a forming method including irradiation of carbon ions after forming a Ta film.

Afterward, as a hard mask layer 5, a silicon oxide film is formed on the carbide layer 4. After that, a photoresist film (not illustrated) is formed on the hard mask layer 5, and is processed into a desired process pattern by photolithography.

Subsequently, the hard mask layer 5 is etched into a desired pattern, for example, by plasma etching using the photoresist film as a mask. Thereby, the hard mask for etching the carbide layer 4 is formed. In this step, a fluorocarbon-based gas, such as CF₄, CHF₃, C₄F₈ or C₄F₆, is used as an etching gas.

Thereafter, an etching mask for etching the film 3 to be etched is formed by etching the carbide layer 4, for example, by plasma etching by using the hard mask as a mask. In this step, for example, 50 sccm of BCl₃ gas, 50 sccm of Cl₂ gas and 100 sccm of Ar gas are mixed together in a plasma processing vessel; the pressure inside the plasma processing vessel is set at 0.7 Pa; a RF electric power for plasma enhancement is set at 1000 watts; and a bias electric power is set at 200 watts.

Afterward, the film 3 to be etched is etched by plasma etching such as RIE using the etching mask as a mask, for example, with the wafer heated at a temperature of 250 to 450° C. In this step, for example, 170 sccm of Cl₂ gas and 30 sccm of O₂ gas are mixed together in the plasma processing vessel; the pressure inside the plasma processing vessel is set at 1 Pa; a RF electric power for plasma enhancement is set at 1000 watts; and a bias electric power is set at 400 watts. The pressure inside the plasma processing vessel is preferably 0.5 to 3 Pa, and more preferably 1 to 2 Pa. In addition, the RF electric power for the plasma enhancement is preferably 200 to 4000 watts, and more preferably 500 to 1500 watts. The bias electric power is preferably 300 to 600 watts, and more preferably 300 to 400 watts.

Table 1 shows the selection ratio of a Pt film to an etching mask in the case where the PT film as the film 3 to be etched is etched by using a Ta film, a Ti film, a TaC film or a TiC film as the etching mask.

As shown in Table 1, in a case where either of a Cl₂/O₂ gas and an Ar gas is used as the etching gas, a film including an element of carbon, like the TaC film or the TiC film, has a greater selection ratio than a film formed from a first metallic element, like the Ta film or Ti film.

The carbide layer 4 using the TaC film, the TiC film or the like is known to have a greater hardness than the carbide layer 4 using the Ta film or the Ti film. In the case of the etching using the Ar gas, for example, the sputtering yield of the film 3 to be etched is almost in proportion to the hardness. For this reason, the etching rate of the mask becomes lower and the selection ratio of the film 3 to be etched to the etching mask accordingly becomes higher in a case where the carbide layer 4 using the TaC film, the TiC film or the like is used as the mask than in a case where the Ta film or the Ti film is used as the mask.

Furthermore, in the case of the etching using the Cl₂ gas, the gas reacts with atoms included in the film 3 to be etched, and the etching progresses while producing volatile PtClₓ.

Moreover, in a case where the carbide layer 4 using the TaC film or the TiC film is used as the mask and a mixture of the Cl₂ gas and the O₂ gas is used as the etching gas, TaOₓ or TiOₓ is produced in the mask. Binding energy of TaOₓ or TiOₓ to the Cl₂ gas is higher than binding energy of Ta or Ti to the Cl₂ gas, and the etching rate of the mask accordingly becomes lower. For this reason, the selection ratio can be enhanced to a large extent.

Accordingly, the taper angle of the Pt film as the film 3 to be etched, which was etched by the above-mentioned etching method, was 82 degrees when the Ta film was used as the etching mask, and 86 degrees when the TaC film was used as the etching mask.

As described above, the first embodiment uses the etching mask including the element of carbon and a first metallic element to thereby increase the selection ratio of the film 3 to be etched to the etching mask, and accordingly can almost perpendicularly etch the film 3 to be etched.

| | Ta | Ti | TaC | TiC |
|---|---|---|---|---|
| Cl₂/O₂ | 2.4 | 1.8 | 6.2 | 7.9 |
| Ar | 2.8 | 2.4 | 5.3 | 4.8 |

### Second Embodiment

As a second embodiment, descriptions will be provided hereinbelow for a method of manufacturing semiconductor device. The embodiment is the application of the etching method of the first embodiment to a method of manufacturing a magnetic random access memory.

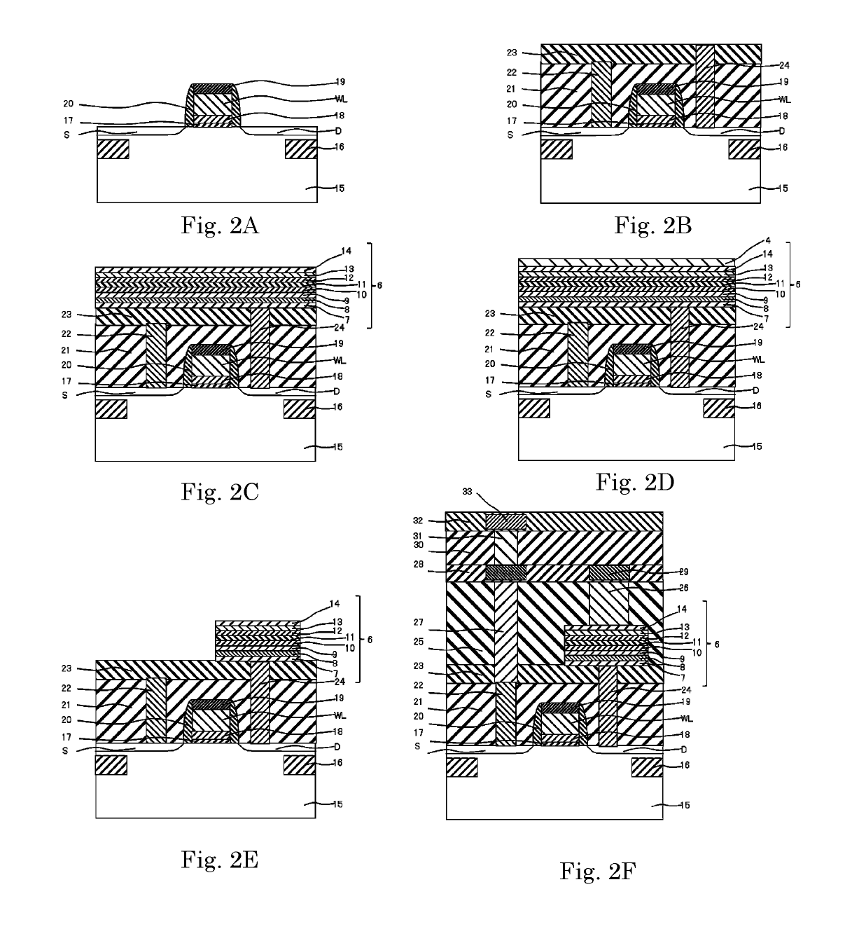

FIGS. 2A to 2F are cross-sectional views showing the semiconductor device manufacturing method of the second embodiment.

As shown in FIG. 2A, a STI (Shallow Trench Isolation) structure is formed by: forming element separation grooves in a semiconductor substrate 15; and embedding element separation insulating films 16, for example silicon oxide films, into the element separation grooves. Thereafter, as a gate insulating film 17, a silicon oxide film is formed on the semiconductor substrate 15; and as a gate electrode 18, an n-type poly-silicon film is formed on the gate insulating film 17. Subsequently, as a word line WL, for example, a WSix film is formed on the gate electrode 18; and as a nitride film 19, for example, a SiN film is formed on the word line WL. Afterward, select transistor stacked films are formed by etching the nitride film 19, the word line WL, the gate electrode 18 and the gate insulting film 17. After that, a spacer film 20 is formed by: overlaying, for example, a silicon nitride film as a nitride film, on the semiconductor substrate 15 in a way that covers the select transistor stacked films; and etching back this nitride film. Subsequently, a select transistor is formed by forming a source region S and a drain region D in the semiconductor substrate 15 through ion implantation using the nitride film 19 and the spacer film 20 as masks.

As shown in FIG. 2B, thereafter, as a first insulating film 21, for example, a silicon oxide film is formed on the semiconductor substrate 15 by plasma CVD (Chemical Vapor Deposition) in a way that covers a first protective film. Afterward, a contact hole is formed by lithography and RIE (Reactive Ion Etching) in a way that exposes the source region to the outside.

After that, as a metal barrier film (not illustrated), a Ti film and a TiN film are formed inside this contact hole by sputtering or CVD under a forming gas atmosphere. Subsequently, a contact plug material is formed on the metal barrier film. The contact plug material is, for example, a W film formed by CVD. Thereafter, the contact plug material and the metal barrier film are flattened by CMP (Chemical Mechanical Polishing). Thereby, a first contact plug 22 communicating with the source region S is formed in the first insulating film 21.

Subsequently, a nitride film 23 is formed on the first insulting film 21 and the first contact plug 22 by CVD. Thereafter, a contact hole communicating with the drain region D is formed. Afterward, a metal barrier film (not illustrated) is formed inside the contact hole; and as a second contact plug material 24, a W film is formed on the metal barrier film. After that, a second contact plug 24 is formed by polishing using a CMP process. Thereby, the second contact plug 24 communicating with the drain region D is formed in the first insulating film 21.

Thereafter, as shown in FIG. 2C, a magnetoresistive effect element 6 is formed on the first contact plug 22, the second contact plug 24 and the first insulating film 21. As a lower electrode 7, a Ta film with a film thickness of 50 Å is formed on the first contact plug 22, the second contact plug 24 and the first insulating film 21. Instead, a film 3 to be etched, such a Pt layer, a Ru layer or an Ir layer, may be used.

Afterward, as an orientation controlling film 8, for example, a Pt film with a film thickness of 50 Å is formed on the lower electrode 7. After that, as a first magnetic layer 9, a magnetic reference layer is formed on the orientation controlling film 8. The magnetic reference layer is, for example, a CoPt layer with a film thickness of 10 Å. Subsequently, as a first interface magnetic layer 10, for example, an amorphous Co₄₀Fe₄₀B₂₀ layer with a film thickness of 10 Å is formed on the first magnetic layer 9.

Subsequently, as a nonmagnetic layer 11, a tunnel insulating film of amorphous MgO with a film thickness of 10 Å is formed on the first interface magnetic layer 10. Thereafter, as a second interface magnetic layer 12, for example, an amorphous Co₄₀Fe₄₀B₂₀ layer with a film thickness of 10 Å is formed on the nonmagnetic layer 11.

Afterward, as a second magnetic layer 13, a magnetic storage layer is formed on the second interface magnetic layer 12. The magnetic storage layer has a Co/Pt artificial lattice, for example, formed with Co films and Pt films stacked alternately.

After that, as an upper electrode 14, a Ta layer with a film thickness of 100 Å is formed on the second magnetic layer 13. Instead, a film 3 to be etched, such as a Ru layer, may be used as the upper electrode 14.

Through the foregoing steps, the magnetoresistive effect element 6 is formed. In the magnetoresistive effect element 6, the magnetic, reference layer is used as the first magnetic layer 9, while the magnetic storage layer is used as the second magnetic layer 13. Instead, the magnetic storage layer and the magnetic reference layer may be used as the first magnetic layer 9 and the second magnetic layer 13, respectively.

In the foregoing steps, the lower electrode 7, the orientation controlling layer 8, the first magnetic layer 9, the first interface magnetic layer 10, the nonmagnetic layer 11, the second interface magnetic layer 12, the second magnetic layer 13 and the upper electrode 14 are formed by sputtering, for example.

Subsequently, a thermal process is carried out in vacuum at a temperature of 300 to 350° C. for approximately one hour. Thereby, MgO used as the nonmagnetic layer 11 is crystallized; and through the thermal process, the amorphous Co₄₀Fe₄B₂₀ used as the first interface magnetic layer 10 and the second interface magnetic layer 12 is crystallized into Co50Fe50.

As shown in FIG. 2D, thereafter, as a carbide layer 4, a TaC film, for example, is formed on the upper electrode 14 by sputtering with TaC used as a target. Instead, the carbide layer 4 may be a TiC film.

After that, as a hard mask layer (not illustrated), for example, a silicon oxide film is formed on the carbide layer 4 by CVD.

Afterward, a photoresist film (not illustrated) is formed on the hard mask layer, and is processed into a desired process pattern by photolithography.

Subsequently, a hard mask for etching the carbide layer 4 is formed by etching the hard mask layer into a desired pattern, for example, by plasma etching using the photoresist film as a mask.

Thereafter, an etching mask for etching the noble metal is formed by etching the carbide layer 4 by RIE using the hard mask as a mask.

Afterward, as shown in FIG. 2E, the magnetoresistive effect element, the lower electrode and the upper electrode each having the film 3 to be etched are etched by RIE. More specifically, the upper electrode 14, the second magnetic layer 13, the second interface magnetic layer 12, the nonmagnetic layer 11, the first interface magnetic layer 10, the first magnetic layer 9, the orientation controlling layer 8 and the lower electrode 7 are etched.

In this step, the embodiment uses a layer including a first metallic element and the element of carbon, such as the TaC film, as the etching mask. Thereby, the magnetoresistive effect element, the lower electrode and the upper electrode each including the noble metal can be etched almost perpendicularly.

Subsequently, as a protective film (not illustrated) for the magnetoresistive effect element 6, a silicon nitride film is formed by CVD in a way that covers the magnetoresistive effect element 6.

As shown in FIG. 2F, thereafter, as a second insulating film 25, for example, a silicon oxide film is formed on the nitride film 23 in a way that covers the protective film (not illustrated).

Afterward, a third contact plug 26 connected to the upper electrode 14 of the magnetoresistive effect element 6 and a fourth contact plug 27 connected to the first contact plug 22 are formed. These contact plugs 26, 7 are formed by: forming their contact holes in the second insulating film 25 by lithography and RIE; thereafter embedding Al into the contact holes; and applying a CMP process.

After that, an oxide film 28 is formed on the second insulating film 25, the third contact plug 26 and the fourth contact plug 27. Thereafter, grooves for forming first interconnections 29 are formed by processing the oxide film 28 using lithography and RIE in a way that exposes the third contact plug 26 and the fourth contact plug 27 to the outside. Subsequently, the first interconnections 29 are formed by: embedding Al into the grooves; and applying a CMP process.

Afterward, a third insulating film 30 is formed on the oxide film 28 and the first interconnections 29. After that, a via hole is formed by processing the third insulating film 30 by lithography and RIE in a way that exposes one of the first interconnections 29 to the outside. Subsequently, a via plug 31 is formed by: embedding Al into this via hole; and applying a CMP process.

Thereafter, an oxide film 32 is formed on the third insulating film 30 and the via plug 31. Afterward, an interconnection groove for forming a second interconnection 33 is formed by processing the oxide film 32 by lithography and RIE in a way that exposes the via plug 31 to the outside. After that, the second interconnection 33 is formed by: embedding Al into this interconnection groove; and applying a CMP process.

Incidentally, a Cu interconnection may be formed by use of a damascene process. In this case, the interconnection is obtained by: forming a Ta/TaN barrier film and a Cu seed layer; and performing an embedding process by Cu plating.

Through the foregoing manufacturing steps, the magnetic random access memory is formed as the semiconductor device of the second embodiment.

As described above, the second embodiment of the present invention uses the film including a first metallic element and the element of carbon, such as the TaC film, as the etching mask. This makes it possible to increase the selection ratio of the magnetoresistive effect element or the lower or upper electrode, which includes a noble metal, with respect to the etching mask, and to etch the magnetoresistive effect element or the like almost perpendicularly.

It should be noted that: the application of the etching method of the first embodiment is not limited to the above-described method of manufacturing a magnetic random access memory; and the etching method of the first embodiment can be also applied to the etching of an electrode or the like, which includes a film to be etched, in a ferroelectric memory, and to other cases.

The second embodiment has been described on the assumption that the magnetic storage layer is used as the first magnetic layer 9 while the magnetic reference layer is used as the second magnetic layer 13. However, the magnetic reference layer and the magnetic storage layer may be used as the first magnetic layer 9 and the second magnetic layer 13, respectively.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An etching method comprising:
forming a film to be etched, which includes a first metallic element, on a semiconductor substrate;
forming a carbide layer, the carbide layer including a second metallic element, on the film to be etched;
etching the carbide layer into a desired pattern; and
etching the film to be etched by using the carbide layer as a mask.

2. The etching method of claim 1, wherein
the first metallic element is an element selected from Pt, Au, Ag, Ir, Pd, Rh, Ru and Os, and
the second metallic element is an element selected from Ti, Ta, W, Mo, Nb and Hf.

3. The etching method of claim 1, wherein the carbide layer is any one of a TaC film and a TiC film.

4. The etching method of claim 1, wherein the etching of the film to be etched is plasma etching performed with a Cl₂ gas and an O₂ gas being supplied.

5. The etching method of claim 1, further comprising:
forming a hard mask layer on the carbide layer, and thereafter etching the hard mask layer; and
etching the carbide layer by using the hard mask layer as a mask.

6. The etching method of claim 5, wherein the hard mask layer is a silicon oxide film.

7. The etching method of claim 5, wherein the etching of the hard mask layer is plasma etching performed with a fluorocarbon gas being supplied.

8. A method of manufacturing semiconductor device comprising:
forming a stack structure above a substrate, the stack structure including a lower electrode, a magnetoresistive effect element, and an upper electrode, the stack structure including a first metallic element;
forming a carbide layer, which includes a second metallic element, on the stack structure;
etching the carbide layer into a desired pattern; and
etching the upper electrode, the magnetoresistive effect element and the lower electrode by using the carbide layer as a mask.

9. The semiconductor device manufacturing method of claim 8, wherein the first metallic element is included in at least one of the upper electrode and the lower electrode.

10. The semiconductor device manufacturing method of claim 8, wherein
the first metallic element is an element selected from Pt, Au, Ag, Ir, Pd, Rh, Ru and Os, and
the second metallic element is an element selected from Ti, Ta, W, Mo, Nb and Hf.

11. The semiconductor device manufacturing method of claim 8, wherein the carbide layer is anyone of a TaC film and a TiC film.

12. The semiconductor device manufacturing method of claim 8, wherein the etching of the upper electrode, the magnetoresistive effect element and the lower electrode is plasma etching performed with a Cl₂ gas and an O₂ gas being supplied.

13. The semiconductor device manufacturing method of claim 8, further comprising:
forming a hard mask layer on the carbide layer, and thereafter etching the hard mask layer; and
etching the carbide layer by using the hard mask layer as a mask.

14. The semiconductor device manufacturing method of claim 13, wherein the hard mask layer is a silicon oxide film.

15. The semiconductor device manufacturing method of claim 14, wherein the etching of the hard mask layer is plasma etching performed with a fluorocarbon gas being supplied.
